(19) United States
(12) Patent Application Publication
(10) Pub. No.: US 2026/0371493 A1
(43) Pub. Date: Nov. 19, 2026

(54) MULTI-MATERIAL PRINTED CIRCUIT BOARD

(71) Applicant: Apple Inc., Cupertino, CA (US)

(72) Inventors: Xinlu Li, Shanghai (CN); Chen Zhang, Shanghai (CN); Chia Chi Wu, Taipei City (TW); Ming Gao, Shanghai (CN)

(21) Appl. No.: 19/208,497

(22) Filed: May 14, 2025

(51) Int. Cl. H05K 1/189; H05K 1/09; H05K 1/11; H05K 1/181

(52) U.S. Cl. CPC H05K 1/189; H05K 1/092; H05K 1/111; H05K 1/181; H05K 2201/09272; H05K 2201/09381; H05K 2201/10492

(57) ABSTRACT

A flexible circuit board can include a substrate, a first conductive component positioned on the substrate, with the first conductive component including a first conductive material, a second conductive component positioned proximal the first conductive component on the substrate, with the second conductive component including the first conductive material, a first trace on the substrate extending from the first conductive component, with the first trace including a second conductive material, a second trace on the substrate extending from the second conductive component, with the second trace including the second conductive material, and an electronic component extending between the first conductive component and the second conductive component.

### FIELD

The present disclosure relates generally to electronic devices. More particularly, the present disclosure relates to printed circuit boards for electronic devices.

### BACKGROUND

Various electronic devices can include printed circuit boards. The electronic devices that use printed circuit boards can include consumer electronics, portable electronic devices, communication devices, and much more. Printed circuit boards include layers of conductive and insulating layers. The conductive layers can be used to connect electronic components together in an electronic circuit. Printed circuit boards can include a single conductive layer, layers on both sides of a substrate layer, or multi-layered. Electronic components can be attached to the printed circuit board, such as, for example, light emitting diodes (LEDs), capacitors, resistors, switches, chips, similar devices, and combinations thereof.

### SUMMARY

At least one example of the present disclosure includes a flexible circuit board including a substrate, a first conductive component positioned on the substrate, the first conductive component including a first conductive material, a second conductive component positioned adjacent to the first conductive component on the substrate, the second conductive component including the first conductive material, a first trace on the substrate extending from the first conductive component, the first trace including a second conductive material, a second trace on the substrate extending from the second conductive component, the second trace including the second conductive material, and an electronic component extending between the first conductive component and the second conductive component.

In one example, the first conductive material comprises copper, nickel, gold, brass, stainless steel, silver, titanium, magnesium, graphite, or a combination thereof. In one example, the second conductive material comprises a silver paste, a copper paste, a nickel paste, a carbon paste, a graphite past, an aluminum paste, a platinum paste, a zinc paste, a tin paste, an ink combined with a conductive metal, polymer combined with a conductive metal, or a combination thereof. In one example, the first conductive component and the second conductive component are separated by a gap and the electronic component extends across the gap. In one example, the flexible circuit board comprises an adhesive configured to couple the first conductive component or the second conductive component to the substrate. In one example, the first trace overlaps a first portion of the first conductive component, and the second trace overlaps a second portion of the second conductive component. In one example, the electronic component is coupled to the first conductive component and the second conductive component with a reflow solder.

In at least one example of the present disclosure, a printed circuit board includes a base, a first pad pair positioned on the base, the first pad pair including a first pad and a second pad, a second pad pair positioned on the base, the second pad pair including a third pad and a fourth pad, and a trace extending from the first pad pair to the second pad pair on the base.

In one example, at least one of the first pad pair and the second pad pair comprises copper, nickel, gold, brass, stainless steel, silver, titanium, magnesium, graphite, or a combination thereof. In one example, the trace includes at least one of: a silver paste, a copper paste, a nickel paste, a carbon paste, a graphite paste, an aluminum paste, a platinum paste, a zinc paste, a tin paste, an ink combined with a conductive metal, polymer combined with a conductive metal, or a combination thereof. In one example, the trace extends from the first pad of the first pad pair to the third pad of the second pad pair. In one example, the trace overlaps a portion of the first pad of the first pad pair, and the trace overlaps a portion of the third pad of the second pad pair. In one example, the printed circuit board further includes a first component coupled to the first pad pair and a second component coupled to the second pad pair.

In at least one example of the present disclosure, a circuit board, comprising: a first non-conductive material; a conductive component pair coupled to the first non-conductive material; a conductive path having a first length extending from the conductive component pair along the first non-conductive material and a second length overlapping a first area portion of the conductive component pair; and a second non-conductive material extending across the first non-conductive material, over the conductive component pair and the conductive path. A second area portion of the conductive component is exposed through the second non-conductive material.

In one example, the conductive component pair includes a first conductive component and a second conductive component, and each of the first conductive component and the second conductive component include an area exposed through the second non-conductive material. In one example, the circuit board further includes a component coupled to the conductive component pair external to the second non-conductive material relative to the first non-conductive material and through the second area portion. In one example, the second non-conductive material extends over the first length and the second length of the conductive path relative to the first non-conductive material. In one example, the second length of the conductive path is positioned between the second non-conductive material and the first area portion of the conductive component pair. In one example, the second area portion of the conductive component is a central area of the conductive component. In one example, the first area portion of the conductive component pair is smaller than the second area portion of the conductive component pair.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 illustrates a perspective view of one example of an electronic device;

FIG. 2 illustrates a schematic top view of one example of a printed circuit board;

FIG. 3A illustrates a top view of a portion of one example of a printed circuit board;

FIG. 3B illustrates a top view of a portion of one example of a printed circuit board;

FIG. 3C illustrates a top view of a portion of one example of a printed circuit board;

FIG. 3D illustrates a top view of a portion of one example of a printed circuit board; and

FIG. 4 illustrates a side cross-sectional view of one example of a printed circuit board, as taken through section line 4-4 in FIG. 3D.

### DETAILED DESCRIPTION

Reference will now be made in detail to representative examples illustrated in the accompanying drawings. It should be understood that the following descriptions are not intended to limit the examples to one preferred example. To the contrary, it is intended to cover alternatives, modifications, and equivalents as can be included within the spirit and scope of the described embodiments as defined by the appended claims.

Printed circuit boards can be created by adding a conductive material to a substrate. The conductive material goes through an etching and stripping process to remove the unnecessary conductive material, leaving the specific conductive configuration on the substrate. In removing the unnecessary conductive material, conductive material is wasted. The process of etching and stripping can require washing and cleaning in a solution. In having to repeat the washing and cleaning processes, additional materials are used, and additional waste is created. The waste can be costly and hazardous to the environment.

In at least one example, a printed circuit board (PCB) can be constructed with conductive pads. Die cutting can be used to create the conductive pads instead of etching the conductive material. In some examples, the die cut pads can be cut as a group or pair of two conductive pads. The conductive pads can be adhered to a substrate, such as by using an adhesive. For example, the die cut conductive pads can be adhered to the substrate as a pair.

By die cutting conductive pads, such as in a pair, the process of creating the printed circuit board can waste less conductive material. The die cut conductive pads can also cost less, due to the reduced waste, and the printed circuit board can require less (or no) washing and cleaning after application of the pads. Therefore, less water and chemicals are used in the process of creating the printed circuit board. Additionally, the overall process can be shorter than a traditional etching process. Therefore, less energy can be required, reducing emissions, electricity costs, and other environmental impacts.

Conductive pads can be electrically coupled to other components (e.g., other conductive pads, voltage sources, ground potentials, etc.) in a circuit configuration using a printed material. In some examples, the printed material can comprise a different conductive material than the conductive pads, such as in a case where the pads comprise a copper material and the printed material comprises a silver material. The printed material can be added after the pads are secured in place on the substrate, and the printed material can be applied overlapping the conductive pads, creating a bridge of conductive material (e.g., a trace) between other points of interest on the printed circuit board. The printing of the second material can reduce wastage, can save energy, and can be generally more efficient at creating a PCB, at least as compared to etching.

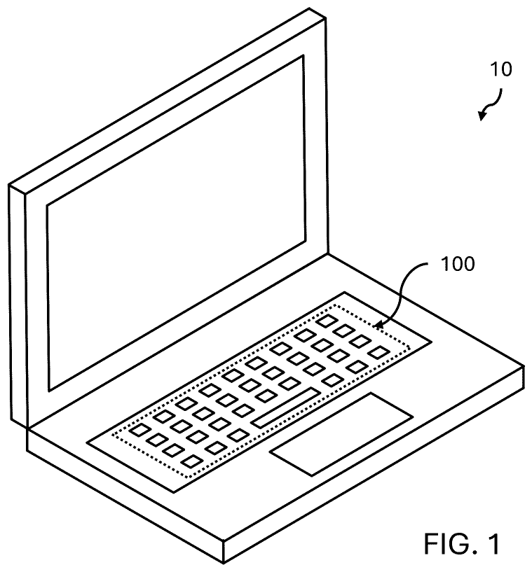

These and other embodiments are discussed below with reference to FIGS. 1-4. However, those skilled in the art will readily appreciate that the detailed description given herein with respect to these figures is for explanatory purposes only and should not be construed as limiting. Furthermore, as used herein, a system, a method, an article, a component, a feature, or a sub-feature including at least one of a first option, a second option, or a third option should be understood as referring to a system, a method, an article, a component, a feature, or a sub-feature that can include one of each listed option (e.g., only one of the first option, only one of the second option, or only one of the third option), multiple of a single listed option (e.g., two or more of the first option), two options simultaneously (e.g., one of the first option and one of the second option), or combination thereof (e.g., two of the first option and one of the second option).

FIG. 1 illustrates a perspective view of one example of an electronic device 10. As shown in FIG. 1, the electronic device 10 can house a variety of components and systems, including a printed circuit board 100. The electronic device 10 can be a portable device, such as a laptop, or can be any device or system that includes a printed circuit board, such as laptops, tablets, mobile devices, keyboards, remotes, and the like. The printed circuit board 100 can include layers of conductive material and insulating material. The printed circuit board 100 can provide a structure or configuration for various electronic components. The printed circuit board 100 can be part of a keyboard or other internal electronic component positioned in a base housing of the electronic device 10. In some examples, the electronic device can include a display housing in which an electronic display is positioned. The PCB 100 can be positioned below a set of key mechanisms and can be used to provide lighting, a set of switches, and other electronic functions to the keyboard area of the electronic device 10. In some examples, the PCB 100 can also be connected to a trackpad or touchpad input device of the electronic device 10. Power to the PCB 100 can be provided by an internal energy source (e.g., a battery) of the electronic device 10 or by an external energy source (e.g., a connection to an electrical utility grid) connected to the PCB 100 and/or electronic device 10.

Any of the features, components, and/or parts, of the printed circuit board 100, including the arrangements and configurations thereof shown in FIG. 1, can be included, either alone or in any combination, in any of the other examples of devices, features, components, and parts shown in the other figures. Likewise, any of the features, components, and/or parts, including the arrangements and configurations thereof shown in the other figures can be included, either alone or in any combination, in the example of the devices, features, components, and parts shown in FIG. 1.

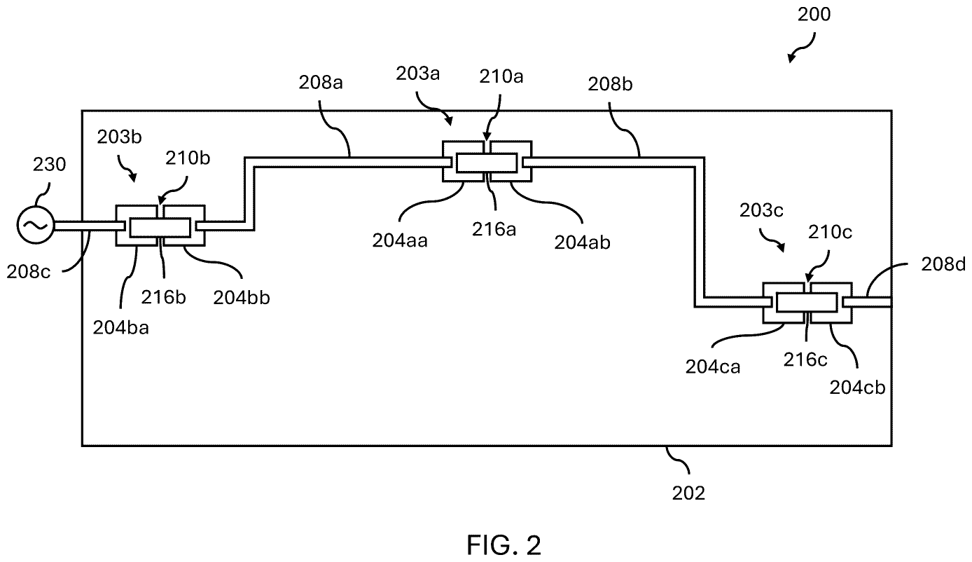

FIG. 2 illustrates a top view of one example of a printed circuit board 200 that can be used as PCB 100. The printed circuit board 200 can include a base 202 (e.g., a substrate or insulator layer), a plurality of pad groups 203a-c (e.g., sets or pairs of conductive pads), and a plurality of traces 208a-d (e.g., conductive paths or routes).

The base 202 can define an area of the printed circuit board 200. The base 202 in FIG. 2 can represent a portion of a larger or more complex printed circuit board. The base 202 can be a non-conductive material, an insulating material, a substrate, a membrane, and the like. For example, the base 202 can be a material that is heat resistant, chemical resistant, rigid, flexible, or a combination thereof. In one example, the base 202 can be a polyimide or a polyethylene terephthalate.

The pad groups 203a-c can comprise at least one conductive material. In one example, the pad groups 203a-c can all comprise the same conductive material. The pad groups 203a-c can be positioned in different areas of the printed circuit board 200. The pad groups 203a-c can be positioned to accommodate various components of the printed circuit board 200 or to align with external components, such as key switches positioned over the printed circuit board 200.

The pad groups 203a-c can each include at least two pads, such as pad pairs including a first pad 204aa (or 204baor 204ca) and a second pad 204ab (or 204bb or 204cb). Each of the first pads 204aa-204ca and second pads 204ab-cb can comprise a conductive material. The pads 204 can therefore be referred to as conductive components. The pads 204aa-204cb can each define a conductive area or a conductive surface. In one example, the pad groups 203a-c can comprise at least one of copper, nickel, silver, stainless steel (e.g., SUS), brass, silver, titanium, magnesium, graphite, similar conductive materials, or combinations thereof. For example, the pad groups 203a-c can include a first material with a plating of a second material. The pad groups 203a-c can have a resistance between about 1.2E-06 Ω−cm to about 2.2E-06 Ω−cm, or about 1.6E-06 Ω−cm to about 1.8E-06 Ω−cm, or about 1.7E-06 Ω−cm. Thus, the pads can be good conductors of electricity and can comprise durable materials such as metal. The pads can beneficially comprise a material well suited to receive and bond with solder used to mount components to the pads.

The pad groups 203a-c can each include a first pad 203aa-ca and a second pad 203ab-cb. The first pads 204aa-204ca can be spaced apart from their respective second pads 204ab-cb to define gaps 210a-c. The gaps 210a-c can aid in maintaining independent conductive areas of the first pads 204aa-ca and second pads 204ab-cb.

Each of the pad groups 203a-c can include a component 216a-c. The components 216a-c can be electrical components of the printed circuit board. The components 216a-c can extend between the first pads 204aa-204ca and the second pads 204ab-cb of their respective pad groups 203a-c. The components 216a-c can be configured to electrically connect the first pads 204aa-204ca and the second pads 204ab-cb of their respective pad groups 203a-c. The components 216a-c can comprise electronic devices such as surface-mount devices (SMDs) designed to be mounted directly onto the pads 204. The components 216a-c can comprise diodes, resistors, capacitors, transistors, integrated circuits (ICs), switches, buttons, inductors, transformers, similar devices, and combinations thereof. The components 216 can be mounted in place on the pads using solder (e.g., via solder pads, solder paste, reflow soldering, vapor phase soldering, or wave soldering), adhesives, or combinations thereof.

Each of the pad groups 203a-c can be electrically coupled to another pad group 203a-c via traces 208a-d. In one example, the traces 208a-d include a second conductive material. For example, the traces 208a-d can include silver paste, copper past, gold paste, nickel paste, carbon/graphite paste, aluminum paste, platinum paste, palladium paste, zinc paste, tin paste, or a combination thereof. The material of the traces 208a-d can be selected to be the same or different from the material used in the pad groups 203a-c. The traces 208a-d can have a resistance between about 1.8E-06 Ω−cm to about 3.2E-06 Ω−cm, or about 0.8E-06 Ω−cm to about 1.7E-06 Ω−cm, or about 3E-06 Ω−cm. The traces 203 a-c can be configured to create and provide at least one conductive path between a first pad group and a second pad group. For example, the first trace 208a can connect the first pad 204aa of the first pad group 203a to the second pad 204bb of the second pad group 203b. The second trace 208b can connect the second pad 204ab of the first pad group 203a to the first pad 204ca of the third pad group 203c. The third trace 208c can connect the first pad 204ba of the second pad group 203b to another pad group, a power source, a voltage source (e.g., a source 230), or other electrical components of the printed circuit board. The fourth trace 208d can connect the second pad 204cb of the third pad group 203c to another pad group, a power source, a voltage source, or other electrical components of the printed circuit board. The pad groups 203a-c and traces 203a-d can create an electrical circuit.

Any of the features, components, and/or parts, of the printed circuit board 200, including the arrangements and configurations thereof shown in FIG. 2, can be included, either alone or in any combination, in any of the other examples of devices, features, components, and parts shown in the other figures. Likewise, any of the features, components, and/or parts, including the arrangements and configurations thereof shown in the other figures can be included, either alone or in any combination, in the example of the devices, features, components, and parts shown in FIG. 2.

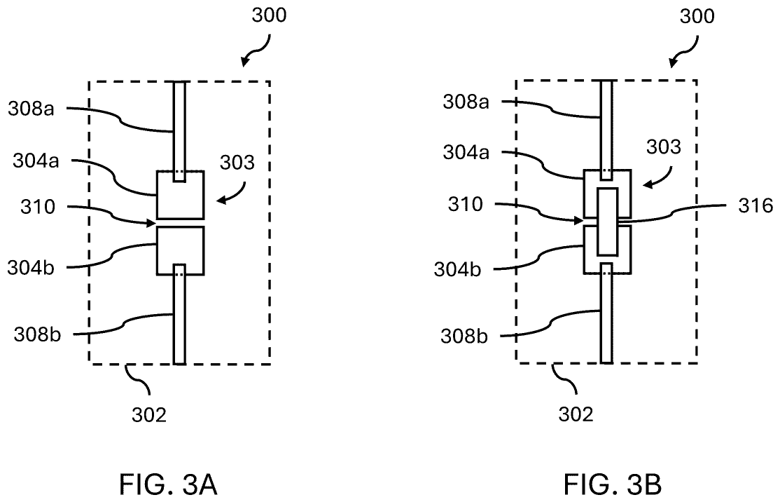

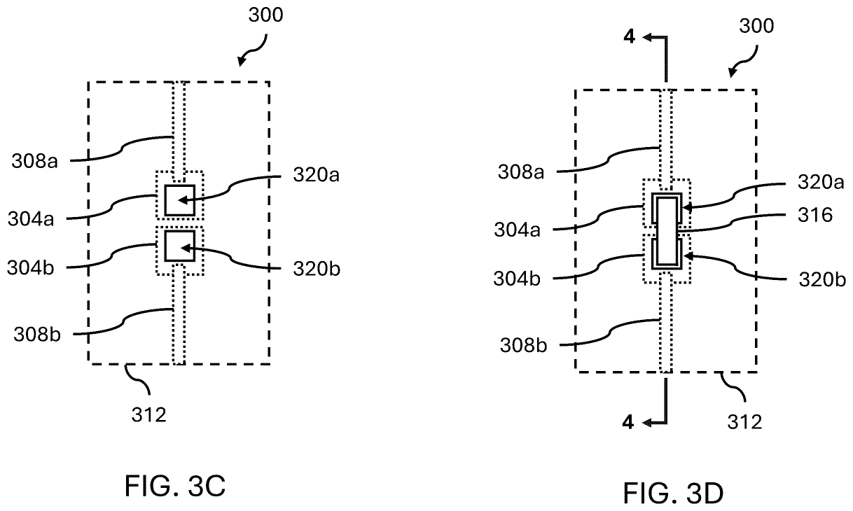

FIG. 3A-3D illustrate various top views of a printed circuit board 300. As illustrated in FIG. 3A-3D, only a portion of the printed circuit board 300 is shown. The printed circuit board 300 can include a base 302, a pad group 303, and traces 308a-b.

The base 302 can be substantially similar to base 202. The base 302 in FIG. 3A-3D can represent a portion of a larger or more complex printed circuit board. The base 302 can support the pad group 303 and the traces 308a-b. In one example, the base 302 can be a non-conductive material, an insulating material, a substrate, a membrane, and the like. The base 302 can be a material that is heat resistant, chemical resistant, flexible, or a combination thereof. In one example, the base 302 can be a polyimide or a polyethylene terephthalate.

The pad group 303 can include a first pad 304a and a second pad 304b. The pad group 303 can include a conductive material. In one example, pad group 303 can be a conductive foil. the pads 304a-b can each define a conductive area. In one example, the pad group 303 can include copper, nickel, silver, stainless steel (e.g., SUS), brass, silver, titanium, magnesium, graphite, a similar material, or a combination thereof. For example, the pad group 303 can include a first material with a plating of a second material. The material of the pad group 303 can have a resistance between about 1.2E-06 Ω-cm to about 2.2E-06 Ω−cm, or about 1.6E-06 Ω-cm to about 1.8E-06 Ω−cm, or about 1.7E-06 Ω−cm. As illustrated in FIG. 3A, the pad group 303 can be placed on the base 302 first. In other words, the pad group 303 can be placed directly on a surface of the base 302 without intervening material, coatings, or parts between the pad group 303 and the base 302.

The pad group 303 can be die cut. The pad group 303 can be die cut as the group of more than one conductive pad, such as the first pad 304a and the second pad 304b being die cut at the same time and from a single piece of source material (e.g., a single sheet of foil). Thus, the pad group 303 can be formed starting with a conductive foil. The conductive foil can be slit or cut into one or more conductive foil strips. The slit conductive material/strips can be die cut into the desired shape and size of the pad group 303. The pad group 303 can be die cut and stored on a tape and reel package prior to use. The pad group 303 can be added to the base 302 using a pick and place machine. The pad group 303 can be placed anywhere on the base 302. The pad group 303 can be placed as a group to maintain accurate spacing, position, or a combination thereof. In one example, the pad group 303 can include an adhesive to secure the pad group 303 to the base 302 with the pad group 303 maintaining the spacing of a gap 310. The pad group 303 can be hot pressed to adhere the pad group 303 to the base 302.

The first pad 304a and the second pad 304b can be separated by the gap 310. The gap 310 can maintain independent conductive areas of the first pad 304a and the second pad 304b. A component 316 can be attached to the pad group 303. The component 316 can be electrical components of the printed circuit board 300, such as the components 216 described above. The component 316 can extend between the first pad 304a and the second pad 304b. The component 316 can be configured to electrically connect the first pad 304a and the second pad 304b. The component 316 can extend over and across the gap 310. In the example illustrated in FIG. 3B, the component 316 is coupled to the first pad group 303. The component 316 can be a surface mount LED, a resistor, a capacitor, or any other electronic component 216 described above.

The traces 308a-b can extend from the pads 304a-b of the pad group 303. In one example, the traces 308a-b include a conductive material. For example, the traces 308a-b can include silver paste, copper paste, gold paste, nickel paste, carbon/graphite paste, aluminum paste, platinum paste, palladium paste, zinc paste, tin paste, an ink/liquid polymer combined with silver, copper, carbon, gold, nickel, aluminum, or another highly conductive material, or a combination thereof. The material of the traces 308a-b can be selected to be the same or different from the material of the pad group 303. The traces 308a-b can have a resistance between about 1.8E-06 Ω−cm to about 3.2E-06 Ω−cm, or about 0.8E-06 Ω−cm to about 1.7E-06 Ω−cm, or about 3E-06 Ω−cm. The traces 203 a-b can be configured to create a conductive path between pad group 303 and other pad groups. For example, the first trace 308a can extend from the first pad 304a to a second pad group to electrically connect the pad group 303 and the second pad group. In one example, the second trace 308b can extend from the first pad 304b to third pad group to electrically connect the pad group 303 and the third pad group. In one example, the traces 308a-b can be configured with additional traces to form a switch. For example, two offset layers of traces with a gap between the layers can create a physical or mechanical switch (e.g., by movement of the layers into contact with each other, such as when pressed together by an input force from a user). In one example, the traces 308a-b can be formed on a membrane and flex with the membrane. In one example, the traces 308a-b can integrate with the base 302 when the base 302 is a membrane.

The traces 308a-b can be printed on the base 302. In one example, the traces 308a-b can be screen printed on the base 302. The traces 308a-b can be added to the base 302 after the pad group 303. In one example, the traces 308a-b can overlap an area or outer exposed surface portion of the pad group 303. The traces 308a-b can be printed to overlap a portion of the pad group 303. The first trace 308a can overlap a portion of the first pad 304a. The second trace 308b can overlap a portion of the second pad 304b. The traces 308a-b overlapping the pad group 303 can increase reliability by ensuring that the traces 308 have a sufficient contact area with the pads 304 to remain in electrical communication with the pads 304 even if the base 302 moves, bends, or flexes. In some examples, the overlapping portion of the traces 308 can extend over and across a single side edge of a generally square or rectangular pad 304, as shown in FIGS. 3A and 3B. The overlapping area of the pad 304 and trace 308 can be a small portion of the total outer surface area of the pad 304, such as less than about ten percent thereof. The width of the traces 308 can be substantially less than the width of the edge of the pad 304 from which the traces 308 extend, such as less than about one half or less than about one third of the width of the overlapped edge of the pad 304.

In some examples, the printed circuit board 300 can include a cover layer 312, as shown in FIGS. 3C and 3D. The cover layer 312 can include a non-conductive material. For example, the cover layer 312 can be a polyimide or a polyethylene terephthalate. The cover layer 312 can be laminated on the printed circuit board 300. In one example, the cover layer 312 can be transparent. The cover layer 312 can be configured to cover the entirety of the base 302. In one example, the cover layer 312 can be configured to entirely and completely cover the traces 308a-b. The cover layer 312 covering the traces 308a-b can protect the printed circuit board 300 from damage. For example, the cover layer 312 can protect from water, moisture, oxygen, and the like.

In one example, the cover layer 312 can define a first opening (at 320a) and a second opening (at 320b) that align with the first pad 304a and the second pad 304b, respectively, to create a first exposed area 320a and a second exposed area 320b. As illustrated in FIGS. 3C and 3D, the exposed areas 320 a-b can be distinct areas defined by the cover layer 312, with one exposed area for each pad 304. In another example, the cover layer 312 can define a single, larger exposed area that exposes an area of the first pad 304a and an area of the second pad 304b through the same single opening. Thus, more than one pad 304 can be exposed through the single larger opening. In various examples, the exposed areas 320a-b can be larger in area than the area of the pads 304a-b overlapped by the traces 308a-b. For instance, the openings in the cover layer 312 can be about 7-10 times larger in area than the areas of the pads 304 a-b overlapped by the traces 308a-b. The exposed areas 320a-b can enable the component 316 to be coupled to the pad group 303. The exposed areas 302a-b can allow multiple layers of the printed circuit device 300 to couple together. The exposed areas 320a-b can be located in substantially central areas of the pads 304a-b, wherein the edges of the pads 304 can be entirely covered by the cover layer 312, and center areas of the pads 304 can be exposed through the openings in the cover layer 312.

In one example, the component 316 can be added after application of the cover layer 312 and external to the cover layer 312 relative to the base 302. The component 316 can couple to the first pad 304a and the second pad 304b through the openings in the cover layer 312. In one example, the component 316 can couple to the first pad 304a through the first exposed area 320a and can couple to the second pad 304b through the second exposed area 320b. In one example, the component 316 can couple to the first pad 304a and the second pad 304b through a single exposed area around or overlapping multiple pads of the pad group 303, such as by including the first pad 304a and the second pad 304b.

The printed circuit board 300 can undergo a surface mount technology (SMT) process. The SMT process can install the component 316 and can cure the traces 308a-b. Although one side of the printed circuit board 300 is shown in the figures, pad groups, traces, and a cover layer can be applied on the other side of the base 302, or multiple layers of pad groups, traces, and cover layers can be used.

Any of the features, components, and/or parts, of the printed circuit board 300 including the arrangements and configurations thereof shown in FIG. 3A-3D can be included, either alone or in any combination, in any of the other examples of devices, features, components, and parts shown in the other figures. Likewise, any of the features, components, and/or parts, including the arrangements and configurations thereof shown in the other figures can be included, either alone or in any combination, in the example of the devices, features, components, and parts shown in FIG. 3A-3D.

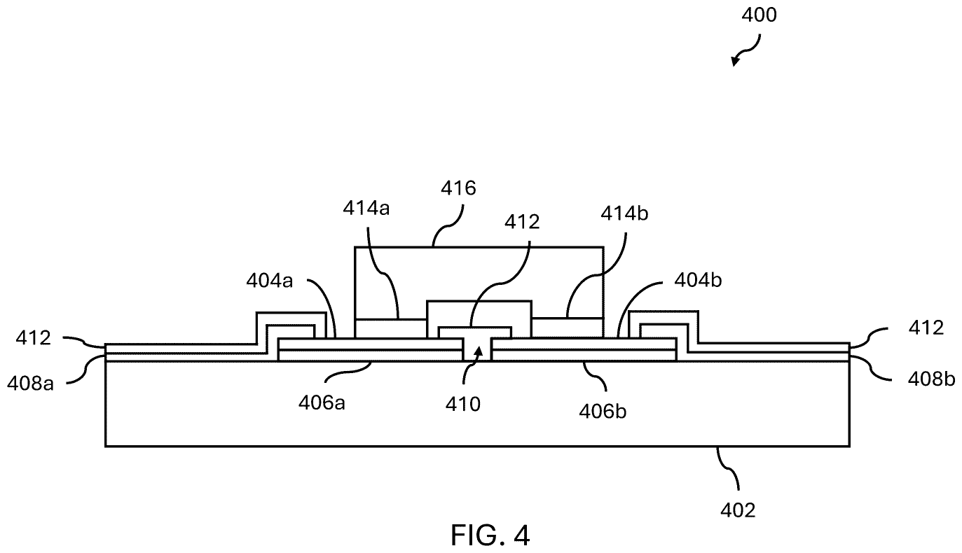

FIG. 4 illustrates a cross-sectional view of one example of a portion of the printed circuit board 300, as taken through section lines 4-4 in FIG. 3D. The printed circuit board 300 can include a base 302, pads 304a-b, traces 308a-b, and a component 316. The base 302 can be substantially similar to bases 202 and 302.

The pads 304a-b can be secured, bonded, or coupled to the base 302 with an adhesive 306a-b. The adhesive 306a-b can be a thermally sensitive adhesive (TSA), a thermosetting adhesive, a thermally stable adhesive, or the like. In one example, the adhesive 306a-b can be activated at a high temperature. For example, the adhesive 306a-b can be activated at a temperature between about 125 degrees Fahrenheit to about 180 degrees Fahrenheit, or between about 145 degrees Fahrenheit to about 160 degrees Fahrenheit, or about 150 degrees Fahrenheit to about 155 degrees Fahrenheit. In one example, the high temperature is applied to the printed circuit board 300 for a specific duration to set the adhesive 306a-b. For example, the high temperature can be applied for a duration of about 10 seconds to about 120 seconds, or about 30 seconds to about 100 seconds. In one example, the adhesive 306a-b is coupled to the pads 304 a-b before the pads 304 a-b are added to the base 302. For example, the adhesive 306a-b can cover substantially the same area of the pad 304a-b as the component 316.

The traces 308a-b can be printed on the base 302 and on the pas 304a-b. In one example, the traces 308a-b can be screen printed on the base 302. The traces 308a-b can be added to the base 402 after the pad group 303 is added, such that the traces 308 overlap the pad group 303 on the exterior side of the pad group 303 relative to the base 302. As illustrated in FIG. 4, the traces 308a-b can overlap a portion of the pads 304a-b. For example, a first length of the traces 308a-b can overlap their respective pads 304a-b, and a second length of the traces 308a-b can be directly on the base 302. In one example, the length of the traces 308a-b overlapping the pads 304a-b is substantially shorter than the length of the traces 308a-b on the base 302. The first trace 308a can overlap a portion of the first pad 304a. The second trace 308b can overlap a portion of the second pad 304b.

The printed circuit board 300 can include a cover layer 312. As illustrated in FIG. 4, the cover layer 312 can extend over the traces 308a-b that cover the pads 304a-b, such that the length of traces 308a-b that overlaps the pads 304a-b can be sandwiched between the pads 304a-b and the cover layer 312. By covering the traces 308a-b, the cover layer 312 can protect the printed circuit board 300 from damage from water, moisture, oxygen, and the like. In one example, the cover layer 312 can define a first opening and a second opening that align with the first pad 304a and the second pad 304b to create one or more exposed areas. As illustrated in FIG. 4, a portion of the cover layer 312 can extend between the first pad 304a and the second pad 304b to create distinct exposed areas. In one example, the cover layer 312 can surround the first pad 304a and the second pad 304b, but not extend between the pads 304a-b. In one example, an area of the portion of the pads 304a-b that is exposed is larger than the area of the pads 304a-b that the traces 308a-b overlap. The openings in the cover layer 312 can enable the component 316 to be coupled to the pads 304a-b.

The component 316 can be an electrical component of the printed circuit board 300. The component 316 can extend between the first pad 304a and the second pad 304b. The component 316 can be configured to electrically connect the first pad 304a and the second pad 304b. The component 316 can extend over the gap 310. As illustrated in FIG. 4, the component 316 can couple to the first pad 304a and the second pad 304b through, over, and across the cover layer 312 or over and across a portion of the cover layer 312 located at the gap 310 and underneath the component 316.

The component 316 can be coupled to the first pad 304a and the second pad 304b with solder 314a-b. In one example, the solder 314a-b can be coupled to the component 316 before the component 316 is placed on the pads 304a-b. For example, the solder 314a-b can reflow during a reflow process to couple the component 316 to the pads 304a-b. In one example, the openings of the cover layer 312 can be sized based on the component 312, such that the component 316 can be constrained in position by the cover layer 312 during a reflow process. The exposed areas 320a, 320b can be sized and positioned to enable precise positioning of the solder 314a-b against the pads 304a-b while minimizing additional exposed surface area of the pads 304a-b to improve reliability of the pads 304a-b and protection provided by the cover layer 312.

The cover layer 312 can completely encapsulate and cover the traces 308a-b applied to the base 302 and pads 304a-b. Thus, the cover layer 312 can include portions externally overlapping the traces 308a-b relative to the base layer 302, as shown by the consistent and entire vertical overlap of the cover layer 312 and traces 308a-b in FIG. 4. Additionally, the cover layer 312 can include portions externally overlapping and covering the traces 308a-b in a horizontal direction (e.g., in directions parallel to the main, flat outer surface of the base 302) to protect the traces 308a-b laterally as well.

Any of the features, components, and/or parts, of the printed circuit board 300, including the arrangements and configurations thereof shown in FIG. 4, can be included, either alone or in any combination, in any of the other examples of devices, features, components, and parts shown in the other figures. Likewise, any of the features, components, and/or parts, including the arrangements and configurations thereof shown in the other figures can be included, either alone or in any combination, in the example of the devices, features, components, and parts shown in FIG. 4.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

What is claimed is:

1. A flexible circuit board, comprising:
a substrate;
a first conductive component positioned on the substrate, the first conductive component comprising a first conductive material;
a second conductive component positioned adjacent to the first conductive component on the substrate, the second conductive component comprising the first conductive material;
a first trace on the substrate extending from the first conductive component, the first trace comprising a second conductive material;
a second trace on the substrate extending from the second conductive component, the second trace comprising the second conductive material; and
an electronic component extending between the first conductive component and the second conductive component.

2. The flexible circuit board of claim 1, wherein the first conductive material comprises copper, nickel, gold, brass, stainless steel, silver, titanium, magnesium, graphite, or a combination thereof.

3. The flexible circuit board of claim 1, wherein the second conductive material comprises a silver paste, a copper paste, a nickel paste, a carbon paste, a graphite paste, an aluminum paste, a platinum paste, a zinc paste, a tin paste, an ink combined with a conductive metal, a polymer combined with a conductive metal, or a combination thereof.

4. The flexible circuit board of claim 1, wherein:
the first conductive component and the second conductive component are separated by a gap, and
the electronic component extends across the gap.

5. The flexible circuit board of claim 1, further comprising an adhesive configured to couple the first conductive component or the second conductive component to the substrate.

6. The flexible circuit board of claim 1, wherein:
the first trace overlaps a first portion of the first conductive component, and
the second trace overlaps a second portion of the second conductive component.

7. The flexible circuit board of claim 1, wherein the electronic component is coupled to the first conductive component and the second conductive component with a reflow solder.

8. A printed circuit board, comprising:
a base;
a first pad pair positioned on the base, the first pad pair comprising a first pad and a second pad;
a second pad pair positioned on the base, the second pad pair comprising a third pad and a fourth pad; and
a trace extending from the first pad pair to the second pad pair on the base.

9. The printed circuit board of claim 8, wherein at least one of the first pad pair and the second pad pair comprises copper, nickel, gold, brass, stainless steel, silver, titanium, magnesium, graphite, or a combination thereof.

10. The printed circuit board of claim 8, wherein the trace comprises at least one of: a silver paste, a copper paste, a nickel paste, a carbon paste, a graphite paste, an aluminum paste, a platinum paste, a zinc paste, a tin paste, an ink combined with a conductive metal, a polymer combined with a conductive metal, or a combination thereof.

11. The printed circuit board of claim 8, wherein the trace extends from the first pad of the first pad pair to the third pad of the second pad pair.

12. The printed circuit board of claim 11, wherein:
the trace overlaps a portion of the first pad of the first pad pair,
and the trace overlaps a portion of the third pad of the second pad pair.

13. The printed circuit board of claim 8, further comprising:
a first component coupled to the first pad pair; and
a second component coupled to the second pad pair.

14. A circuit board, comprising:
a first non-conductive material;
a conductive component pair coupled to the first non-conductive material;
a conductive path having a first length extending from the conductive component pair along the first non-conductive material and a second length overlapping a first area portion of the conductive component pair; and
a second non-conductive material extending across the first non-conductive material, over the conductive component pair and the conductive path,
wherein a second area portion of the conductive component pair is exposed through the second non-conductive material.

15. The circuit board of claim 14, wherein:
the conductive component pair includes a first conductive component and a second conductive component, and
each of the first conductive component and the second conductive component comprises an area exposed through the second non-conductive material.

16. The circuit board of claim 14, further comprising a component coupled to the conductive component pair external to the second non-conductive material relative to the first non-conductive material and through the second area portion.

17. The circuit board of claim 14, wherein the second non-conductive material extends over the first length and the second length of the conductive path relative to the first non-conductive material.

18. The circuit board of claim 14, wherein the second length of the conductive path is positioned between the second non-conductive material and the first area portion of the conductive component pair.

19. The circuit board of claim 14, wherein the second area portion of the conductive component pair is a central area of a conductive component of the conductive component pair.

20. The circuit board of claim 14, wherein the first area portion of the conductive component pair is smaller than the second area portion of the conductive component pair.
